(19) United States
(12) Patent Application Publication
(10) Pub. No.: US 2006/0107992 A1
(43) Pub. Date: May 25, 2006

(54) Solar power plant

(75) Inventors: Alexei Valerevich Karnaukhov, Moscow (RU); Yakov Abrammerovich Goldshtein, Moscow (RU)

Correspondence Address: FRISHAUF, HOLTZ, GOODMAN & CHICK, PC, 220 Fifth Avenue, 16TH Floor, NEW YORK, NY, 10001-7708, US

(73) Assignee: SANPAUER REFLEKT, Moscow (RU)

(21) Appl. No.: 11/318,358

(22) Filed: Dec. 23, 2005

Related U.S. Application Data
(63) Continuation of application No. 10/311,780, filed on Dec. 18, 2002.

(30) Foreign Application Priority Data
Jun. 23, 2000 (RU) 2000116097

(51) Int. Cl. H01L 25/00

(52) U.S. Cl. 136/246

(57) ABSTRACT

The solar power plant contains the radiation concentrator fitted with a drive, the system of Sun tracking with a control unit, and a fixedly attached radiation detector, and the drive is made with a possibility of ensuring a straight-line reciprocating movement of the concentrator, and the concentrator is mirror-based with a cylindrical surface having a guide whose current radius value features a deviation from the average value corresponding to the circumradius of the circular cylinder guide by no more than ±10%, and the radiation detector—photoelectric converter, is located in the focal plane.

This application is a continuation application of application Ser. No. 10/311,780 which is the United States national phase application of International Application PCT/RU01/00219 which was filed Apr. 6, 2001.

The invention is related to solar-energy engineering and may be used in devices concentrating solar radiation.

### PREVIOUS ENGINEERING LEVEL

There are known solar power plants that contain a mirror-based concentrator of solar energy in which focus there is a radiation detector made in the form of a heat exchanger (SU 1190154 A 1, F24J 1/100, 1985), photoelectric or thermo-emission converter (SU 1274032 F 1, H01L 31/00, 1987; SU 1825071 A 1, F24J 2/00, 1996)

The main drawback of this approach, even with a concentrator made rotatable for orienting it towards the Sun, is low efficiency of using solar energy.

A version which is the closest to the invention is a solar power plant containing several concentrators fitted with drives, a system of Sun tracking and a unit of drives control ensuring a possibility of automatic orientation, and a fixedly attached radiation detector (SU 1141275 A 1, F24J 2/00, 1985).

However the system of Sun tracking is rather complicated and expensive, making economically unreasonable the use of such installation in the national economy.

### DISCLOSURE OF THE INVENTION

The invention is aimed at creating a solar power plant with structurally simple concentrator drive and Sun tracking system that would provide for efficient use of solar energy.

The solution of the set task is achieved in such a way, that the solar power plant containing the radiation concentrator fitted with a drive, the system of Sun tracking with a control unit, and a fixedly attached radiation detector, according to the invention, the drive is made with a possibility of ensuring a straight-line reciprocating movement of the concentrator, and the concentrator is mirror-based with a cylindrical surface having a guide whose current radius value features a deviation from the average value corresponding to the circumradius of the circular cylinder guide by no more than ±10%, and the radiation detector—photoelectric converter, is located in the focal plane.

It is preferable that the solar power plant would be made with several radiation concentrators with a fixedly located photoelectric converter placed in the focal plane of each of them, and the concentrators have a common drive ensuring their plane-parallel motion.

Plane-parallel, straight-line motion of the concentrator determines the simplicity of the Sun tracking system drive and reliability of control of the solar power plant for the uniform and efficient guidance of solar beams reflected by the cylindrical surface of the concentrators to the stationary radiation detectors—photoelectric converters, and this, with a selected ratio of geometric parameters, raises the efficiency of direct conversion of solar energy into electric energy.

### BRIEF DESCRIPTION OF DRAWINGS

Shown in FIG. 1 is the schematic general view of the solar power plant.

FIG. 2 shows schematic view of concentrator 1.

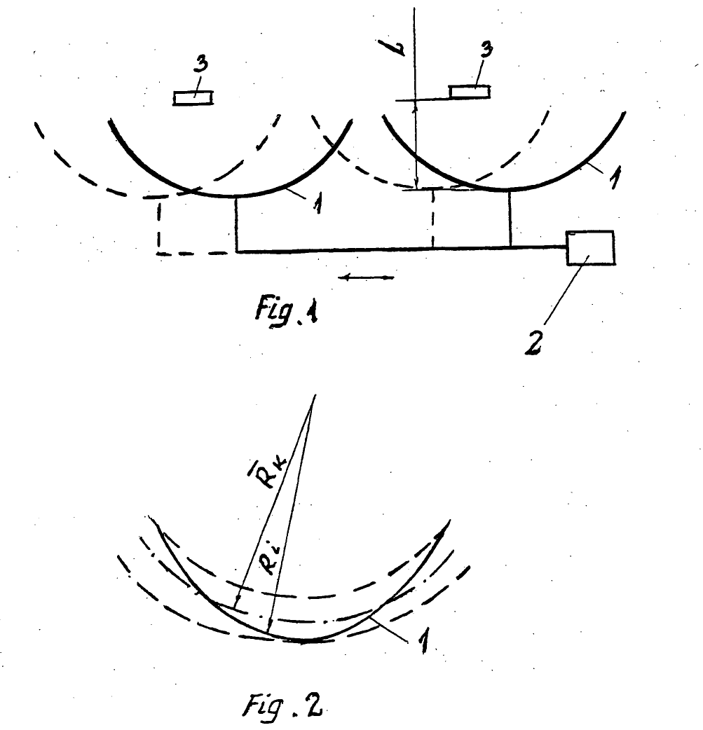

### THE BEST INVENTION EMBODIMENT

The solar power plant contains mirror-based cylindrical radiation concentrators 1 fitted with common drive 2 ensuring the possibility of straight-line reciprocating (plane-parallel) movement of concentrators 1, the Sun tracking system with the control unit (not shown in the drawing), drive 2 and fixedly attached radiation detectors made in the form of photoelectric converters 3 installed in the focal plane.

In this case the solar power plant is characterized by the following ratio of geometrical characteristics:
1,1 Rₖ≧Rᵢ≧0.9 Rₖ;
L=0.5 Rₖ,
where: R—average value of the guide radius corresponding to the circumradius—circular cylinder guide;

Rᵢ—current value of the guide radius of concentrator cylindrical surface;

L—distance from the plane of the photoelectric converter to the concentrator cylindrical surface.

The solar power plant operates in the following way.

Solar beams reflected by mirror-based concentrators 1 fall on photoelectric converters 3 in which direct conversion of light energy into electric energy occurs. In the course of orientation to the Sun the tracking system, as it operates drive 2, realizes such unidimensional (straight-line, plane-parallel) movement of mirror-based concentrators 1 (shown by a dotted line in the drawing) under which the reflected solar beams due to a selected combination of the shapes of concentrators 1 and location of radiation detectors are constantly directed and uniformly distributed over the working surface of photoelectric converters 3 which, with a structural simplicity of drive 2 and tracking system, does ensure the efficiency of the use of the solar power plant for direct conversion of solar energy to electric one even with concentrators 1 surfaces made with a preset deviation from the circular cylinder.

1. A solar power plant containing the radiation concentrator fitted with a drive, the system of Sun tracking with a control unit, and a fixedly attached radiation detector, which is characterized by that the drive is made with a possibility of ensuring a straight-line reciprocating movement of the concentrator, and the concentrator is mirror-based with a cylindrical surface having a guide whose current radius value features a deviation from the average value corresponding to the circumradius of the circular cylinder guide by no more than ±10%, and the radiation detector—photoelectric converter, is located in the focal plane.

2. A solar power plant according to claim 1 characterized by that it is made with several radiation concentrators with a fixedly located photoelectric converter placed in the focal plane of each of them, and the concentrators have a common drive ensuring their plane-parallel movement.
